(19) United States
(12) Patent Application Publication
(10) Pub. No.: US 2025/0123317 A1
(43) Pub. Date: Apr. 17, 2025

(54) TEST CIRCUIT AND TESTING METHOD

(71) Applicant: FUJI ELECTRIC CO., LTD., Kawasaki-shi (JP)

(72) Inventors: Yuki SAWA, Matsumoto-city (JP); Yoshiki TAKESAKO, Matsumoto-city (JP); Toru AJIKI, Matsumoto-city (JP)

(73) Assignee: FUJI ELECTRIC CO., LTD., Kawasaki-shi (JP)

(21) Appl. No.: 18/819,838

(22) Filed: Aug. 29, 2024

(30) Foreign Application Priority Data
Oct. 11, 2023 (JP) 2023-176160

(51) Int. Cl. G01R 31/26

(52) U.S. Cl. CPC G01R 31/261

(57) ABSTRACT

A test circuit for conducting a test on a switching device having a ground electrode, a control electrode, and a power-supply electrode. The test circuit includes: a first terminal configured to be connected to the ground electrode of the switching device; a second terminal configured to be connected to the control electrode of the switching device; a third terminal configured to be connected to the power-supply electrode of the switching device; a fourth terminal configured to receive a power supply voltage; and a first switch connected between the third terminal and the fourth terminal, and being configured to turn off in response to a predetermined time period having elapsed since turning off of the switching device. The predetermined time period is shorter than a time period from when the switching device is turned off to when a drive current flowing through the switching device reaches zero without being interrupted.

### CROSS-REFERENCE TO RELATED APPLICATIONS

The present application claims priority pursuant to 35 U.S.C. § 119 from Japanese patent application number 2023-176160, filed on Oct. 11, 2023, the entire disclosure of which is hereby incorporated by reference herein.

### BACKGROUND

### Technical Field

The present disclosure relates to a test circuit and a testing method.

### Description of the Related Art

Switching devices such as power metal-oxide-semiconductor field-effect transistors (MOSFETs), insulated gate bipolar transistors (IGBTs), and the like are generally subjected to an avalanche test, to be screened for an initial failure and a defective product (Japanese Patent Application Publication Nos. 2013-92534 and 2023-62811).

In the avalanche test, if the peak value of the current flowing through such a switching device is increased, it becomes easier to detect defects in the switching device. However, if the peak value of the current is increased, even normal products with defects that do not matter will be thermally damaged.

### SUMMARY

An aspect of the present disclosure is a test circuit for conducting a test on a switching device, the switching device having a ground electrode, a control electrode, and a power-supply electrode, the test circuit comprising: a first terminal connected to the ground electrode of the switching device; a second terminal connected to the control electrode of the switching device; a third terminal connected to the power-supply electrode of the switching device; a fourth terminal to receive a power supply voltage; and a first switch located between the third terminal and the fourth terminal, wherein the first switch is turned off, in response to a predetermined time period having elapsed since turning off of the switching device, and the predetermined time period is shorter than a first period that is a time period from when the switching device is turned off to when a drive current flowing through the switching device reaches zero without being interrupted.

### BRIEF DESCRIPTION OF THE DRAWINGS

FIG. 1 is a diagram illustrating a system configuration including a test circuit 10.

FIG. 2 is a diagram illustrating a test waveform example.

FIG. 3 is a diagram illustrating a test waveform example.

FIG. 4 is a flowchart illustrating a testing method.

FIG. 5 is a diagram illustrating an example of a relationship between a peak value Icp of a current Ic and energy E.

### DETAILED DESCRIPTION

At least following matters will become apparent from the descriptions of the present Description and the accompanying drawings.

### =====Screening Test=====

A large number of power semiconductor devices (hereinafter, referred to as switching devices) such as power metal-oxide-semiconductor field-effect transistors (MOSFETs) and/or insulated gate bipolar transistors (IGBTs) are formed at a wafer substrate. These switching devices are then separated by dicing and thereafter incorporated into semiconductor modules.

A screening test is a test to evaluate whether switching devices operate normally, to thereby sift out (screen out) ones with initial failure and defective products, and the test is usually conducted in a state of a chip before the switching devices are incorporated into semiconductor modules. The screening test includes dynamic performance tests such as a switching test and an L-load avalanche test (hereinafter, also referred to simply as avalanche test) and static performance tests such as an interelectrode leakage current test and a static withstand voltage test. The following mainly describes a dynamic performance test.

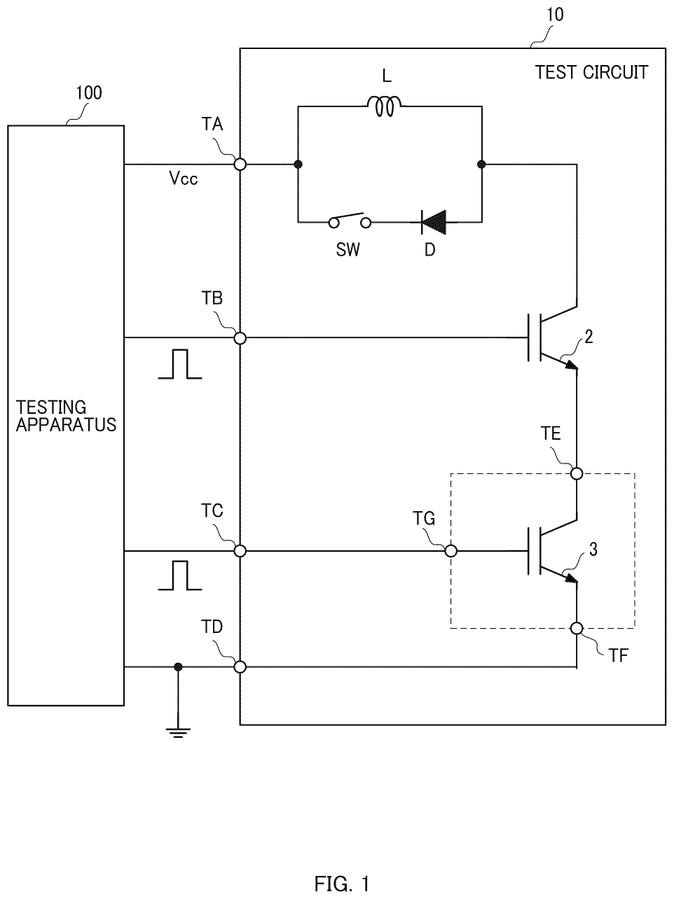

FIG. 1 is a diagram illustrating a system configuration including a test circuit 10. The system illustrated in FIG. 1 includes the test circuit 10 to which a switching device 3, which is to be tested, is mounted and a testing apparatus 100. Here, a description will be given of a case in which the switching device 3 is an IGBT, however, the present disclosure is not limited thereto, and the switching device 3 may be, for example, a MOSFET. Further, the test circuit 10 is connected to the testing apparatus 100.

The testing apparatus 100 conducts a test (screening test) on the switching device 3 through the test circuit 10. The testing apparatus 100 includes a power supply that supplies a power supply voltage Vcc, a driver circuit that outputs drive signals (pulse signals) to turn on and off the switching device 3 and a current interrupting device 2 (described later), a microcomputer that controls the operations of components, and the like (none of these is illustrated). Further, the testing apparatus 100 also includes, for example, a detection circuit (not illustrated) that detects an abnormality such as an overcurrent by monitoring current values and voltage values during the test.

The test circuit 10 is supplied with the power supply voltage Vcc, the drive signals (pulse signals), and a ground voltage (GND potential) from the testing apparatus 100, to conduct a test on the switching device 3. As illustrated in FIG. 1, the test circuit 10 includes terminals TA to TG.

The terminals TA to TD are connected to the testing apparatus 100. The terminal TE is connected to the terminal on the power-supply side of the switching device 3. The terminal TG is connected to the control terminal of the switching device 3, and the terminal TF is connected to the terminal on the ground side of the switching device 3.

As illustrated in FIG. 1, the test circuit 10 includes the terminals TA to TG, a coil L, a regenerative diode D, a switch SW, and the current interrupting device 2. In FIG. 1, a part excluding the region surrounded by a broken line (the switching device 3) corresponds to the test circuit 10. Note that the members configuring the test circuit 10 (the coil L, the regenerative diode D, the switch SW, the current interrupting device 2, and the terminals) may be provided to one substrate or provided to a plurality of substrates separately.

The terminal TA receives the power supply voltage Vcc from the testing apparatus 100. The terminal TB receives a drive signal for the current interrupting device 2 from the testing apparatus 100. The terminal TC receives a drive signal for the switching device 3 from the testing apparatus 100. The terminal TD receives a voltage of a ground level from the testing apparatus 100. The terminal TE is connected to the collector electrode (hereinafter, also referred to simply as collector) of the switching device 3. Note that the collector electrode corresponds to a “power-supply electrode”.

The terminal TF is connected to the emitter electrode (hereinafter also referred to simply as emitter) of the switching device 3, and is connected to the terminal TD in the test circuit 10. The emitter electrode corresponds to a “ground electrode”.

The terminal TG is connected to the gate electrode (hereinafter also referred to simply as gate) of the switching device 3, and is connected to the terminal TC in the test circuit 10. Note that the gate electrode corresponds to a “control electrode”.

Further, the terminal TF corresponds to a “first terminal”, the terminal TG corresponds to a “second terminal”, the terminal TE corresponds to a “third terminal”, and the terminal TA corresponds to a “fourth terminal”.

The coil L is a load (inductive load) provided between the terminal TA and the switching device 3, and is applied with the power supply voltage Vcc through the terminal TA.

The regenerative diode D and the switch SW are connected in series, and are provided in parallel with the coil L. Note that the switch SW corresponds to a “second switch”.

The current interrupting device 2 is a switching device to interrupt a current supplied to the switching device 3 in the event of an abnormality, and is located between the coil L and the switching device 3 (more specifically, the terminal TE). Further, the drive signal is inputted to the gate of the current interrupting device 2 through the terminal TB. Note that although an IGBT is used as the current interrupting device 2 in an embodiment of the present disclosure, the present disclosure is not limited thereto and, for example, a MOSFET or a switch may be used instead. Note that the current interrupting device 2 corresponds to a “first switch”.

On and off of the current interrupting device 2 and switching device 3 are controlled in response to the drive signals received from the testing apparatus 100. For example, when the switching device 3 is tested, a rectangular drive signal (pulse signal) is received from the testing apparatus 100. The switching device 3 is on when the drive signal is high, and is off when the drive signal is low. Note that the drive signal inputted to the current interrupting device 2 is given as a pulsed signal in FIG. 1, for convenience, however, the drive signal outputted from the testing apparatus 100 to the current interrupting device 2 is usually high, and goes low only when the current flowing through the switching device 3 is interrupted or when an abnormality such as an overcurrent is detected. In other words, the current interrupting device 2 is turned off only when the current flowing through the switching device is interrupted or when an abnormality is detected.

### <Test Using Test Circuit 10>

The test circuit 10 illustrated in FIG. 1 can conduct a switching test and an avalanche test as a dynamic performance test.

In the switching test, the switch SW is turned on (electrically connected), to monitor a change in current and a change in voltage when the drive signal (pulse signal) is applied to the gate of the switching device 3 through a gate resistor (not illustrated). In this event, with the switch SW being on, the following free-wheeling path is formed: the coil L→the regenerative diode D→the coil L. Then, for example, in response to a counter-electromotive voltage being generated upon turning off of the switching device 3, most of the voltage flows to the free-wheeling path, so that the energy stored in the coil L is consumed by a resistance component of the coil L.

In the avalanche test, the switch SW is turned off (not electrically connected) and the drive signal (pulse signal) is applied to the gate of the switching device 3 through a gate resistor (not illustrated). Then, the electrical energy is stored in the coil L while the switching device 3 is on, and the energy stored in the coil L is applied to the switching device 3 when the switching device 3 is turned off, to thereby test robustness. Specifically, an electric field is applied between the collector and emitter of the switching device 3 to deplete the gate layer, to thereby break a defective portion due to latch up because of avalanche breakdown (an increase in current due to carries generated in the depletion layer). In this avalanche test, high energy can be applied with a low current and high voltage.

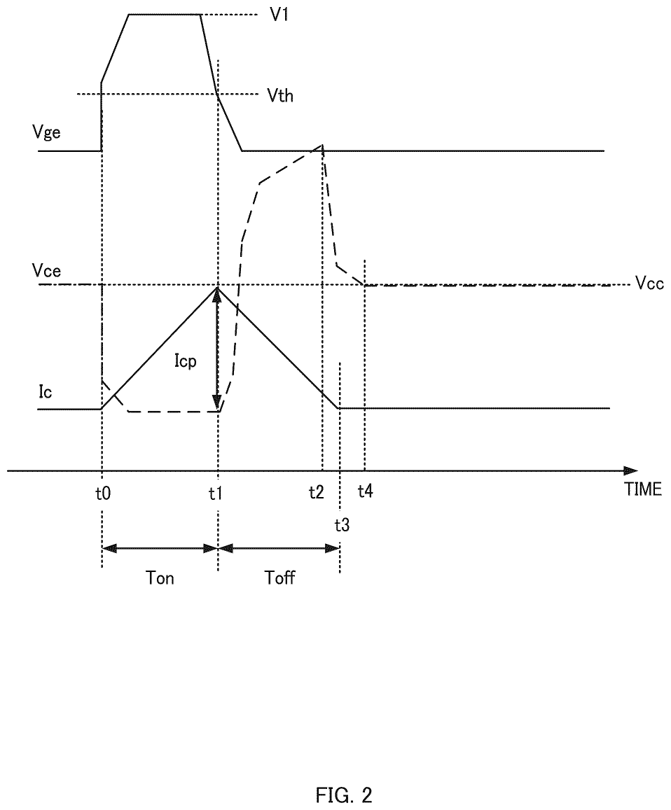

FIG. 2 is a diagram illustrating a test waveform example. In FIG. 2, the switching device 3 is off before time to.

At time to, the gate-emitter voltage (Vge) exceeds a threshold (Vth), to thereby turn on the switching device 3. In association therewith, the voltage Vce reaches substantially zero, and the collector current Ic (hereinafter, referred to as current Ic) increases. At time t1, the voltage (Vge) drops below the threshold (Vth), to thereby turn off the switching device 3. Meanwhile, the current Ic reaches its peak value Icp at time t1 and decreases thereafter. Further, the voltage Vce rises rapidly from time t1, to thereby reach its maximum at time t2. Thereafter, at time t3, the current Ic reaches zero. Then, at time t4, the voltage Vce returns to the same state as the state before time to. By conducting a test with such waveforms, a current can be concentrated in a defective portion, thereby being able to detect a defect.

Note that the peak value (Icp) of the current Ic in FIG. 2 can be given by the following Expression (1):

$$Icp = Vcc \times Ton / L \qquad ( 1 )$$

where L is the inductance of the coil, and Ton (hereinafter, referred to as ON period) is the time period during which the switching device 3 is on in response to the drive signal.

Further, the peak value Icp varies with the ON period Ton, based on the above-described Expression (1). Accordingly, the longer the ON period Ton, the larger the peak value Icp of the current Ic when the switching device 3 is turned off.

Furthermore, when an OFF period Toff is defined as the time period from time t1 to the time when the current Ic reaches zero (that is, time t3), the following Expression holds. Note that the OFF period Toff corresponds to a “first period”, and the current Ic corresponds to a “drive current”.

$$Toff = ( Vcc / ( Vce - Vcc ) ) \times Ton \qquad ( 2 )$$

In order to detect defects in the switching device 3 more in a test using waveforms such as those illustrated in FIG. 2, it is effective to increase the peak value Icp. However, if the peak value Icp is large, there is a risk that damage to the switching device 3 may increase. Specifically, for example, if the energy E generated in the switching device 3 during the OFF period Toff reaches energy Eava, at which thermal damage occurs in the switching device 3, the switching device 3 is thermally damaged.

Further, in an embodiment of the present disclosure, the “energy E” generated in the switching device 3 is determined by integrating the result of multiplying the voltage Vce and the current Ic over the time period during which the current Ic flows.

Further, if the energy E reaches the energy Eava, the switching device 3 is thermally damaged. However, the energy E can be reduced by interrupting the current Ic before the OFF period Toff has elapsed since turning off of the switching device 3. The following describes the case in which the current Ic is interrupted before the OFF period Toff has elapsed.

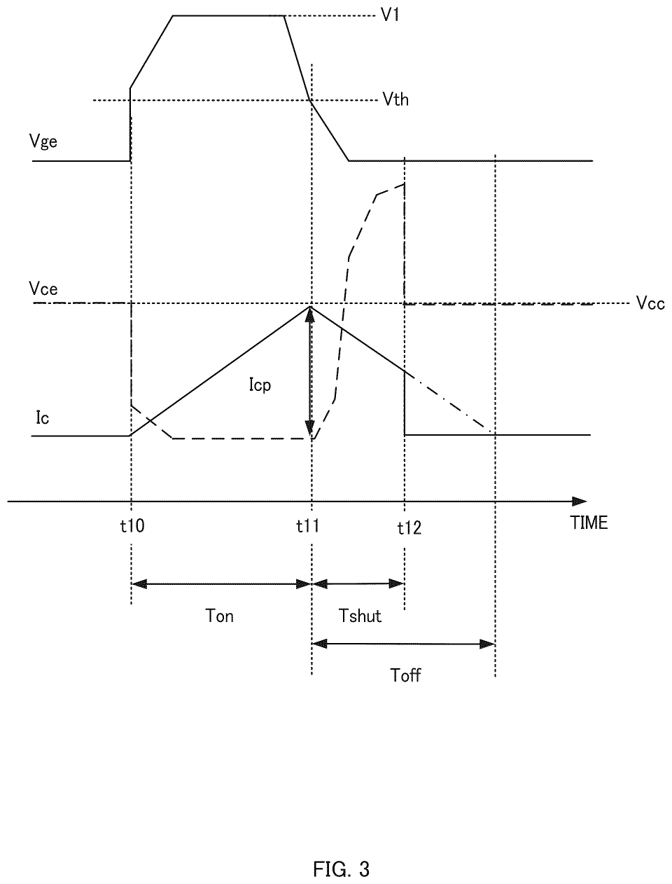

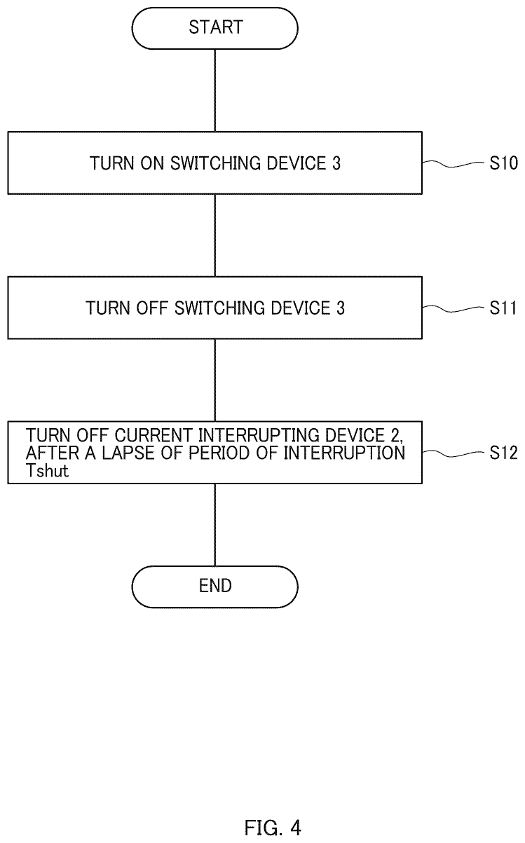

FIG. 3 is a diagram illustrating a test waveform example. FIG. 4 is a flow chart illustrating a testing method. As will be described later in detail, in FIG. 3, when entering a period of interruption Tshut after turning off of the switching device, the current Ic is interrupted.

Here, when the current Ic is interrupted after the period of interruption Tshut has elapsed, “energy E0” generated in the switching device 3 is determined by integrating the result of multiplying the voltage Vce and the current Ic over the period of interruption Tshut.

In an embodiment of the present disclosure, the period of interruption Tshut is determined based on the above-described Expression (2) such that the period of interruption Tshut is shorter than the OFF period Toff, which varies with the ON period Ton, and such that the energy E0 is smaller than the energy Eava. This suppresses thermal damage to the switching device 3. The energy E0 corresponds to a “first energy”, and the energy Eava corresponds to a “second energy”.

Note that FIG. 3 illustrates the OFF period Toff determined according to the ON period Ton, for convenience. Further, the period of interruption Tshut corresponds to a “predetermined period”. In addition, in FIG. 3, before time t10, the switching device 3 is off.

At time t10, the gate-emitter voltage (Vge) exceeds the threshold value (Vth), and the switching device 3 is turned on (step S10: a first step). In association therewith, the voltage Vce reaches substantially zero and the current Ic increases. In addition, at time t11 at which the ON period Ton has elapsed since time t10, the voltage (Vge) drops below the threshold value (Vth), to thereby turn off the switching device 3 (step S11: a second step). At time t11, the current Ic reaches the peak value Icp, and thereafter starts decreasing. Further, from time t11, the voltage Vce rises rapidly.

At time t12 at which the period of interruption Tshut has elapsed since time t11, the current interrupting device 2 is turned off after the switch SW is turned on (step S12: a third step). As a result, a free-wheeling path is formed: the coil L→the regenerative diode D→the coil L, and the current Ic is interrupted.

Note that the period of interruption Tshut may be determined so as to be able to efficiently screen for defects that occur during manufacturing, on the basis of the results of screening the multiple switching devices 3 based on the predetermined ON period Ton. Further, the period of interruption Tshut may also be determined, on the basis of the time period from the turning off of the switching device 3 until the current Ic decreases from the peak value Icp by a predetermined percentage.

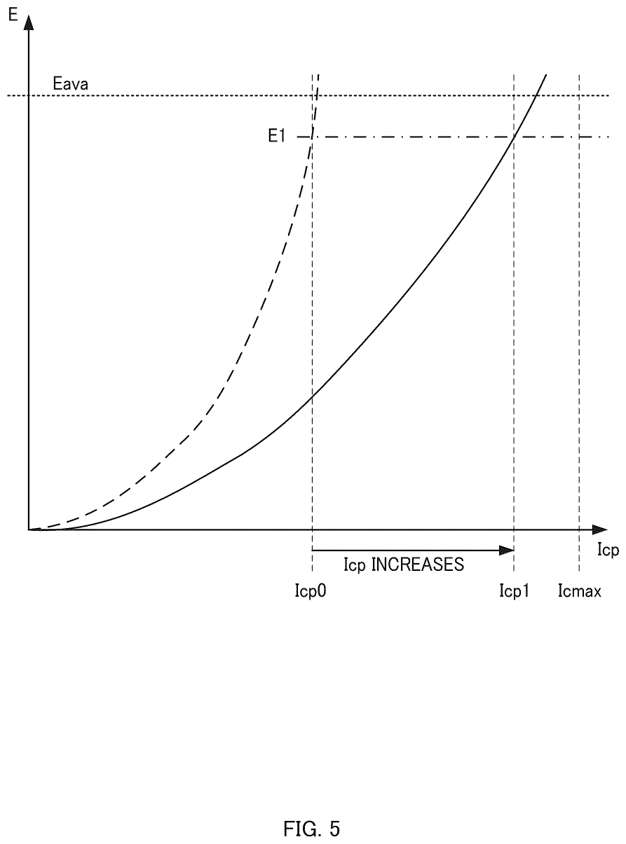

FIG. 5 is a diagram illustrating an example of the relationship between the peak value Icp of the current Ic and the energy E. FIG. 5 is a diagram illustrating how the energy E after the switching device 3 is turned off increases with an increase in the peak value Icp of the current Ic.

Further, the relationship between the current Icp and the energy E when waiting for the OFF period Toff to elapse after the switching device 3 is turned off is given by a dashed line. Meanwhile, the relationship between the peak value Icp of the current Ic and the energy E0 in the case where the current Ic is interrupted in response to the period of interruption Tshut having elapsed after the switching device is turned off is given by a solid line.

Further, the energy E0 varies with the peak value Icp and the period of interruption Tshut. Accordingly, the relationship between the peak value Icp and the energy E0 given by the solid line in FIG. 5 is illustrated assuming that the period of interruption Tshut is a time period satisfying the above-described condition.

Note that in FIG. 5, when an ON period Ton0 is determined such that the energy E reaches energy E1, the peak value Icp of the current Ic results in a peak value Icp0. Here, the energy E1 is energy obtained by lowering the energy Eava, at which thermal damage to the switching device 3 is caused, by a predetermined level (that is, an amount corresponding to a margin for the energy Eava).

Further, when the peak value Icp of the current Ic is a peak value Icp0 (that is, the ON period Ton is the ON period Ton0), the energy E0 (given by the solid line) in the case where the current Ic is interrupted is smaller than the energy E (given by the dashed line) in the case where the current Ic is not interrupted.

Further, when an ON period Ton1 is determined such that the energy E0 reaches the energy E1, the ON period Ton1 is longer than the ON period Ton0, and the peak value Icp of the current Ic is a peak value Icp1 that is larger than the peak value Icp0. Note that the peak value Icp1 is smaller than the current value Icmax, which is the rated current of the switching device 3.

Accordingly, interrupting the current Ic after a lapse of the period of interruption Tshut can suppress thermal damage to normal products while facilitating detection of defects by increasing the peak value Icp of the current Ic.

### Summary

The test circuit 10 according to one embodiment of the present disclosure has been described above. The test circuit 10 includes terminals TA, TE, TG, and TF, and the current interrupting device 2, wherein the current interrupting device 2 is turned off, in response to the period of interruption Tshut having elapsed since turning off of the switching device 3. Further, the period of interruption Tshut is shorter than the OFF period Toff. This makes it possible to suppress thermal damage to the switching device while facilitating detection of defects.

The energy E0 is smaller than the energy Eava. This makes it possible to reliably suppress thermal damage to the switching device 3.

The peak value Icp1 of the current Ic is smaller than the current value Icmax, which is the rated current of the switching device 3. This makes it possible to facilitate detection of defects in the switching device 3 while suppressing damage to the switching device 3.

The test circuit 10 further includes the coil L and the switch SW. The switch SW is turned on after the period of interruption Tshut has elapsed since turning off of the switching device 3. This makes it possible to lower the voltage Vce applied to the collector of the switching device 3.

The switch SW is turned on before the current interrupting device 2 is turned off. This makes it possible to maintain the voltage Vce applied to the switching device 3 at a predetermined level, even if the current interrupting device 2 is turned off.

The method of testing the switching device 3 includes preparing the test circuit 10, the first step, the second step, and the third step, and the period of interruption Tshut is shorter than the OFF period Toff. This makes it possible to achieve a testing method capable of suppressing thermal damage to switching devices while facilitating detection of defects.

The present disclosure is directed to suppression of thermal damage to switching devices while facilitating detection of defects.

According to the present disclosure, it is possible to suppress thermal damage to switching devices while facilitating detection of defects.

What is claimed is:

1. A test circuit for conducting a test on a switching device, the switching device having a ground electrode, a control electrode, and a power-supply electrode, the test circuit comprising:
a first terminal configured to be connected to the ground electrode of the switching device;
a second terminal configured to be connected to the control electrode of the switching device;
a third terminal configured to be connected to the power-supply electrode of the switching device;
a fourth terminal configured to receive a power supply voltage; and
a first switch connected between the third terminal and the fourth terminal, the first switch being configured to turn off in response to a predetermined time period having elapsed since turning off of the switching device, wherein
the predetermined time period is shorter than a first period that is a time period from when the switching device is turned off to when a drive current flowing through the switching device reaches zero without being interrupted.

2. The test circuit according to claim 1, wherein
first energy, which is determined based on a voltage applied to the third terminal and the drive current in the predetermined period, is smaller than second energy, at which thermal damage to the switching device occurs.

3. The test circuit according to claim 2, wherein
a peak value of the drive current when the switching device is turned off is smaller than a rated current of the switching device.

4. The test circuit according to claim 1, further comprising:
a coil provided between the fourth terminal and the first switch; and
a second switch provided in parallel with the coil, wherein
the second switch is configured to turn on after the predetermined period has elapsed since turning off of the switching device.

5. The test circuit according to claim 4, wherein
the second switch is configured to turn on before the first switch is turned off.

6. A testing method of conducting a test on a switching device, the switching device having a ground electrode, a control electrode, and a power-supply electrode, the testing method comprising:
preparing a test circuit having first to fourth terminals and a first switch connected between the third terminal and the fourth terminal, connecting the first to third terminals respectively to the ground electrode, the control electrode, and the power-supply electrode of the switching device, and configuring the fourth terminal to receive a power supply voltage;
a first step of turning on the switching device;
a second step of turning off the switching device; and
a third step of turning off the first switch, in response to a predetermined time period having elapsed since turning off of the switching device, wherein
the predetermined time period is shorter than a first period that is a time period from when the switching device is turned off to when a drive current flowing through the switching device reaches zero without being interrupted.
